(19) United States
(12) Patent Application Publication
(10) Pub. No.: US 2012/0243193 A1
(43) Pub. Date: Sep. 27, 2012

(54) MOTHERBOARD INTERCONNECTION DEVICE AND MOTHERBOARD INTERCONNECTION METHOD

(75) Inventors: CHIA-NAN PAI, Tu-Cheng (TW); SHOU-KUO HSU, Tu-Cheng (TW)

(73) Assignee: HON HAI PRECISION INDUSTRY CO., LTD., Tu-Cheng (TW)

(21) Appl. No.: 13/491,526

(22) Filed: Jun. 7, 2012

Related U.S. Application Data
(63) Continuation-in-part of application No. 12/503,680, filed on Jul. 15, 2009.

(30) Foreign Application Priority Data
Apr. 29, 2009 (CN) 200910301984.6

(51) Int. Cl. H05K 1/18

(52) U.S. Cl. 361/767

(57) ABSTRACT

A motherboard interconnection method includes positioning a first and a third electronic elements on a top layer of a motherboard interconnection device, and positioning a second and a fourth electronic elements on a bottom layer of the motherboard interconnection device. The method connects a first end of the first electronic element on the top layer to the first end of the second electronic element on the bottom layer with a first via hole, and connects the first end of the third electronic element on the top layer to the first end of the fourth electronic element on the bottom layer with a second via hole. The method further connects a second ends of the two electronic elements on the top layer to a first part, and connects the second ends of the two electronic elements on the bottom layer to a second part.

### CROSS-REFERENCE TO RELATED APPLICATIONS

This application is a continuation-in-part application of U.S. Ser. No. 12/503,680, filed Jul. 15, 2009.

### BACKGROUND

1. Technical Field

Embodiments of the present disclosure relate to motherboard design methods, and particularly to a motherboard interconnection device and motherboard interconnection method.

2. Description of Related Art

Motherboard layout is an important phase in the manufacturing process of a motherboard and is closely related to product quality. If two different kinds of parts are installed on the motherboard, a co-lay method is used to connect the different parts (refer to FIG. 1). Co-lay is a process where one part 1 is electronically connected to the motherboard through another part 2. However, as shown in FIG. 1, if only the part 1 is used (i.e., part 2 is removed from the motherboard), then the connection to the other part 2 becomes a stub, and the stub can interfere with a differential signal transmitted by the part 1.

### BRIEF DESCRIPTION OF THE DRAWINGS

FIG. 1 is a schematic diagram of one embodiment of a motherboard interconnection method in a prior art;

FIG. 2 is a schematic diagram of a first embodiment of a motherboard interconnection method provided in the present application;

FIG. 3A is a schematic diagram of a second embodiment of a motherboard interconnection method provided in the present application;

FIG. 3B is a schematic diagram of a third embodiment of a motherboard interconnection method provided in the present application;

FIG. 4A is a schematic diagram of one embodiment of a simulation result of a differential signal transmitted by a first part of FIG. 1;

FIG. 4B is a schematic diagram of one embodiment of a simulation result of a differential signal transmitted by a second part of FIG. 1;

FIG. 5A is a schematic diagram of one embodiment of a simulation result of a differential signal transmitted by the first part of FIG. 2; and

FIG. 5B is a schematic diagram of one embodiment of a simulation result of a differential signal transmitted by the second part of FIG. 2.

### DETAILED DESCRIPTION

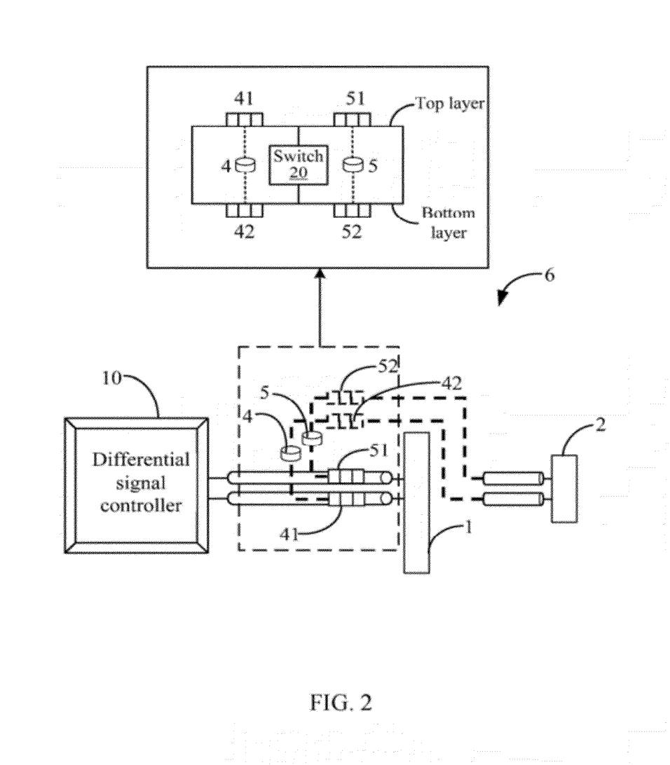

FIG. 2 is a schematic diagram of a first embodiment of a motherboard interconnection device 6. In the first embodiment, at first, two electronic elements, such as a capacitor 41 and a capacitor 51, are positioned on a top layer of the motherboard interconnection device 6, and another two electronic elements, such as a capacitor 42 and a capacitor 52, are positioned on a bottom layer of the motherboard interconnection device 6. In the first embodiment, a switch 20 is used in the motherboard interconnection device 6 and is connected to the top layer of the motherboard interconnection device 6 if a first part 1 is used, or connected to the bottom layer of the motherboard interconnection device 6 if a second part 2 is used. The switch 20 may be a hardware component or a software element. In other embodiments, the electronic elements may be resistors.

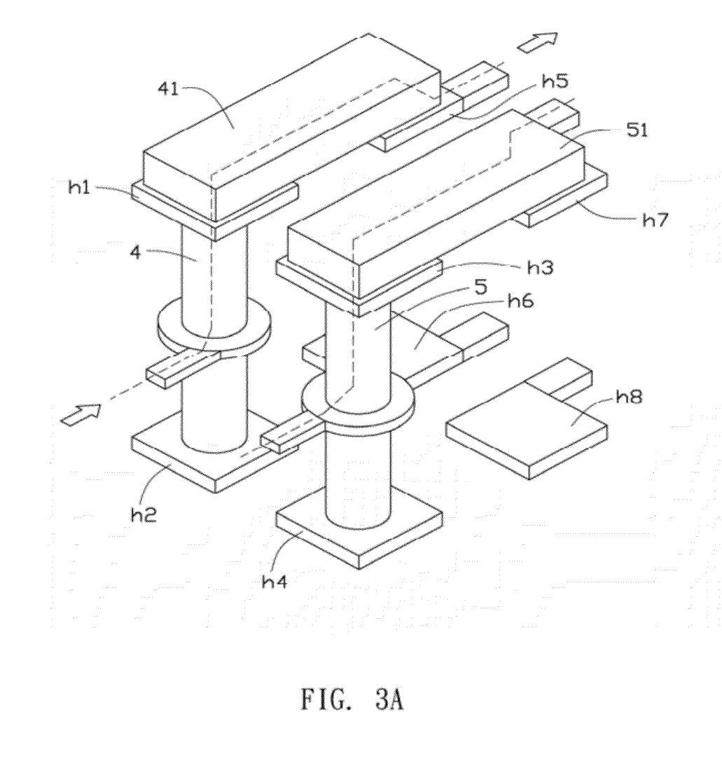

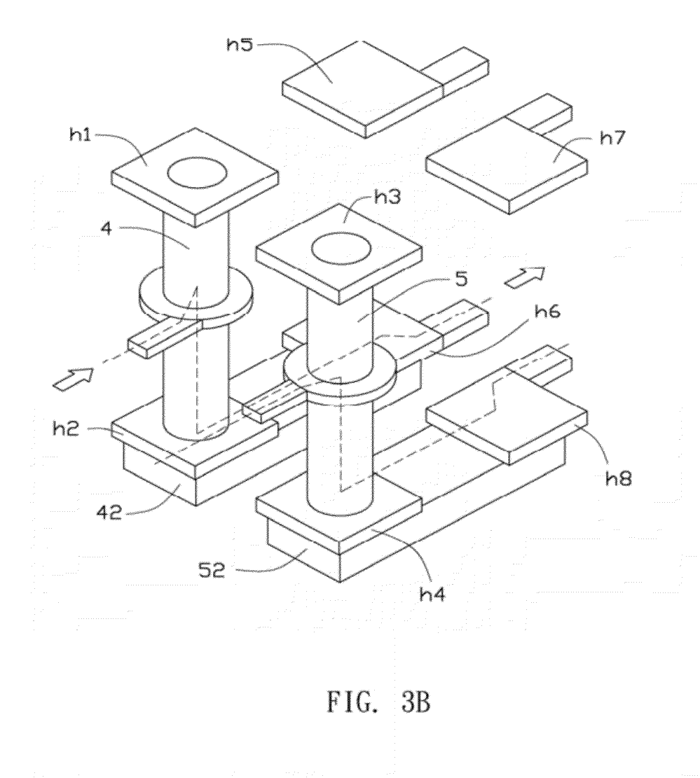

FIG. 3A is a schematic diagram of a second embodiment of the motherboard interconnection device 6. In the second embodiment, the electronic elements (e.g., the capacitor 41 and the capacitor 51) are only positioned on the top layer of the motherboard interconnection device 6, namely, the capacitor 42 and the capacitor 52 are removed from the bottom layer of the motherboard interconnection device 6 (i.e., the second part 2 is removed). Thus, the switch 20 is removed from the motherboard interconnection device 6.

FIG. 3B is a schematic diagram of a third embodiment of the motherboard interconnection device 6. In the third embodiment, the electronic elements (e.g., the capacitor 42 and the capacitor 52) are only positioned on the bottom layer of the motherboard interconnection device 6, namely, the capacitor 41 and the capacitor 51 are removed from the top layer of the motherboard interconnection device 6 (i.e., the first part 1 is removed). Thus, the switch 20 is also removed from the motherboard interconnection device 6.

Second, in the first embodiment, a first via hole 4 is connected to a first bonding pad h1 of one end of the capacitor 41 of the top layer, and a second bonding pad h2 of the same end of the capacitor 42 on the bottom layer corresponding to the capacitor 41. In the second embodiment, the first via hole 4 is connected to the first bonding pad h1 of one end of the capacitor 41 of the top layer. In the third embodiment, the first via hole 4 is connected to the second bonding pad h2 of the same end of the capacitor 42 on the bottom layer corresponding to the capacitor 41.

Third, in the first embodiment, a second via hole 5 is connected to a third bonding pad h3 of the same end of the capacitor 51 of the top layer, and a fourth bonding pad h4 of the same end of the capacitor 52 on the bottom layer corresponding to the capacitor 51. In the second embodiment, the second via hole 5 is merely connected to the third bonding pad h3 of the same end of the capacitor 51 of the top layer. In the third embodiment, the second via hole 5 is merely connected to the fourth bonding pad h4 of the same end of the capacitor 52 on the bottom layer corresponding to the capacitor 51.

Fourth, in the first embodiment, the first part 1 is connected to a bonding pad h5 of the capacitor 41 and a bonding pad h7 of the capacitor 51 on the top layer of the motherboard interconnection device 6, and the second part 2 is connected to a bonding pad h6 of the capacitor 42 and a bonding pad h8 of the capacitor 52 on the bottom layer of the motherboard interconnection device 6. In the second embodiment, only the first part 1 is connected to the bonding pad h5 of the capacitor 41 and the bonding pad h7 of the capacitor 51 on the top layer of the motherboard interconnection device 6. In the third embodiment, only the second part 2 is connected to the bonding pad h6 of the capacitor 42 and the bonding pad h8 of the capacitor 52 on the bottom layer of the motherboard interconnection device 6. In the present application, a type of the first part 1 is different from a type of the second part 2.

In the first embodiment, if only the first part 1 is used, the two electronic elements on the top layer (e.g., the capacitor 41 and the capacitor 51) of the motherboard interconnection device 6 are connected to the first part 1, and differential signals sent by a differential signal controller 10 are transmitted to the first part 1 through the two electronic elements on the top layer of the motherboard interconnection device 6 (refer to a broken line shown in FIG. 3A). For example, the differential signal controller 10 is positioned on a north bridge or a south bridge of the motherboard interconnection device 6. It should be noted that the differential signal controller 10 may be positioned on other suitable electronic devices, such as a central processing unit (CPU).

In the first embodiment, if only the second part 2 is used, the two electronic elements on the bottom layer (e.g., the capacitor 42 and the capacitor 52) of the motherboard interconnection device 6 are connected to the second part 2, and differential signals sent by the differential signal controller 10 are transmitted to the second part 2 through the two electronic elements on the bottom layer of the motherboard interconnection device 6 (refer to a broken line shown in FIG. 3B).

In the second embodiment, the two electronic elements on the top layer (e.g., the capacitor 41 and the capacitor 51) of the motherboard interconnection device 6 are connected to the first part 1, and differential signals sent by the differential signal controller 10 are transmitted to the first part 1 through the two electronic elements on the top layer of the motherboard interconnection device 6 (refer to a broken line shown in FIG. 3A).

In the third embodiment, the two electronic elements on the bottom layer (e.g., the capacitor 42 and the capacitor 52) of the motherboard interconnection device 6 are connected to the second part 2, and differential signals sent by the differential signal controller 10 are transmitted to the second part 2 through the two electronic elements on the bottom layer of the motherboard interconnection device 6 (refer to a broken line shown in FIG. 3B).

In other embodiments, the first part 1 may be connected to the bonding pad h6 of the capacitor 42 and the bonding pad h8 of the capacitor 52 on the bottom layer of the motherboard interconnection device 6, and the second part 2 may be connected to the bonding pad h5 of the capacitor 41 and the bonding pad h7 of the capacitor 51 on the top layer of the motherboard interconnection device 6.

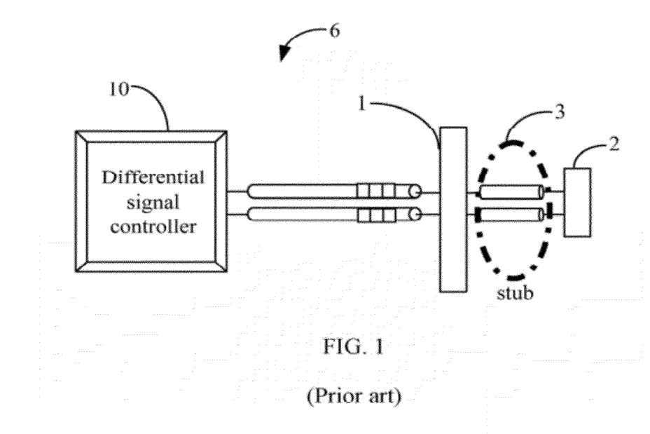

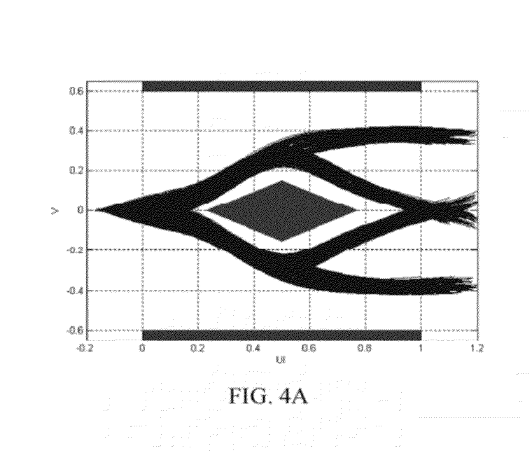

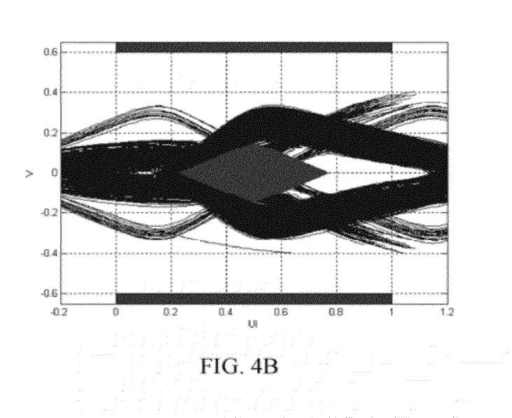

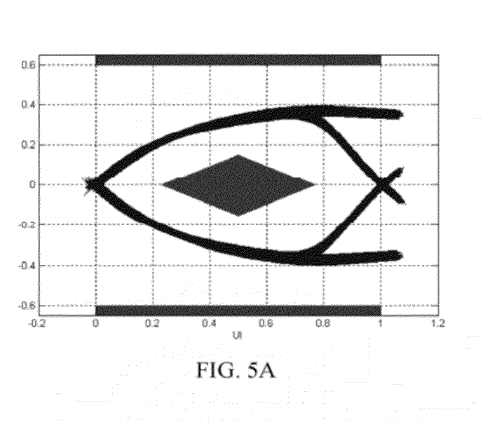

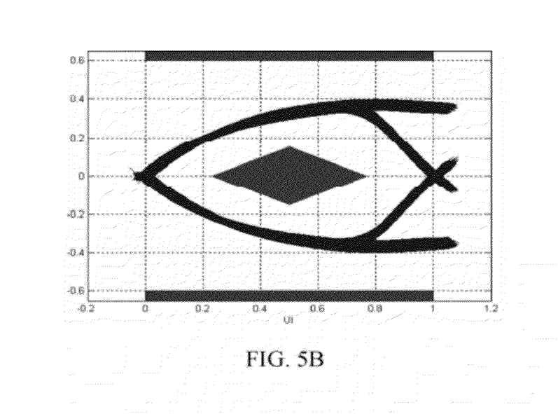

FIG. 4A is a schematic diagram of one embodiment of a simulation result of a differential signal transmitted by the first part 1 of FIG. 1, and FIG. 5A is a schematic diagram of one embodiment of a simulation result of a differential signal transmitted by the first part 1 of FIG. 2. In one exemplary example, a length of the stub in FIG. 4A is 800 mil, and the stub in FIG. 5A is substantially removed. Thus, quality of the differential signal transmitted by the first part 1 of FIG. 2 is better than quality of the differential signal transmitted by the first part 1 of FIG. 1.

FIG. 4B is a schematic diagram of one embodiment of a simulation result of a differential signal transmitted by the second part 2 of FIG. 1, and FIG. 5B is a schematic diagram of one embodiment of a simulation result of a differential signal transmitted by the second part 2 of FIG. 2. In one exemplary example, a length of the stub in FIG. 4B is 1600 mil, and the stub in FIG. 5B is substantially removed. Thus, quality of the differential signal transmitted by the second part 2 of FIG. 2 is better than quality of the differential signal transmitted by the second part 2 of FIG. 1.

In the present embodiments, the first part 1 and/or the second part 2 of the motherboard interconnection device 6 are connected with the via hole 4 and the via hole 5, so as to improve quality of the differential signal transmitted by the first part 1 or the second part 2.

It should be emphasized that the above-described embodiments of the present disclosure, particularly, any embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

What is claimed is:

1. A motherboard interconnection method, comprising:
providing a motherboard interconnection device comprising a first and a third electronic element on a top layer of the motherboard interconnection device, the motherboard interconnection device further comprising a second and a fourth electronic element on a bottom layer of the motherboard interconnection device;
connecting a first bonding pad of a first end of the first electronic element on the top layer to a second bonding pad of the first end of the second electronic element on the bottom layer corresponding to the first electronic element on the top layer with a first via hole;
connecting a third bonding pad of the first end of the third electronic element on the top layer to a fourth bonding pad of the first end of the fourth electronic element on the bottom layer corresponding to the third electronic element on the top layer with a second via hole;
connecting a first part to a bonding pad of a second end of the first and the third electronic elements on the top layer; and
connecting a second part to a bonding pad of the second end of the second and the fourth electronic elements on the bottom layer.

2. The method according to claim 1, wherein the first, second, third, and fourth electronic elements are selected from the group consisting of a capacitor and a resistor.

3. The method according to claim 1, wherein a type of the first part is different from a type of the second part.

4. The method according to claim 3, wherein the first and the third electronic elements on the top layer are connected to the first part, and differential signals are transmitted to the first part through the first and the third electronic elements on the top layer of the motherboard interconnection device.

5. The method according to claim 3, wherein the second and the fourth electronic elements on the bottom layer are connected to the second part, and differential signals are transmitted to the second part through the second and the fourth electronic elements on the bottom layer of the motherboard interconnection device.

6. A motherboard interconnection method, comprising:
providing a motherboard interconnection device comprising a first and a second electronic element on a top layer of the motherboard interconnection device;
connecting a first via hole to a first bonding pad of a first end of the first electronic element on the top layer;
connecting a second via hole to a second bonding pad of the first end of the second electronic element on the top layer; and
connecting a first part to a bonding pad of a second end of the first and the third electronic elements on the top layer.

7. The motherboard interconnection method according to claim 6, wherein the first and the second electronic elements are selected from the group consisting of a capacitor and a resistor.

8. The motherboard interconnection method according to claim 6, wherein the first and the second electronic elements on the top layer are connected to the first part, and differential signals are transmitted to the first part through the first and the second electronic elements on the top layer of the motherboard interconnection device.

9. A motherboard interconnection method, comprising:
providing a motherboard interconnection device comprising a first and a second electronic element on a bottom layer of the motherboard interconnection device;
connecting a first via hole to a first bonding pad of a first end of the first electronic element on the bottom layer;
connecting a second via hole to a second bonding pad of the first end of the second electronic element on the bottom layer; and
connecting a first part to a bonding pad of a second end of the first and the second electronic elements on the bottom layer.

10. The motherboard interconnection method according to claim 9, wherein the first and the second electronic elements are selected from the group consisting of a capacitor and a resistor.

11. The motherboard interconnection method according to claim 9, wherein the first and the second electronic elements on the bottom layer are connected to the first part, and differential signals are transmitted to the first part through the first and the second electronic elements on the bottom layer of the motherboard interconnection device.

12. A motherboard interconnection device, comprising:
a first and a second electronic element positioned on a top layer of the motherboard interconnection device;
a first via hole that connects to a first bonding pad of a first end of the first electronic element on the top layer;
a second via hole that connects to a second bonding pad of the first end of the second electronic element on the top layer; and
a first part that connects to a bonding pad of a second end of the first and the second electronic elements on the top layer.

13. The motherboard interconnection device according to claim 12, wherein the first and the second electronic elements are selected from the group consisting of a capacitor and a resistor.

14. The motherboard interconnection device according to claim 12, wherein the first and the second electronic elements on the top layer are connected to the first part, and differential signals are transmitted to the first part through the first and the second electronic elements on the top layer of the motherboard interconnection device.

15. A motherboard interconnection device, comprising:
a first and a second electronic element positioned on a bottom layer of the motherboard interconnection device;
a first via hole that connects to a first bonding pad of a first end of the first electronic element on the bottom layer;
a second via hole that connects to a second bonding pad of the first end of the second electronic element on the bottom layer; and
a first part that connects to a bonding pad of a second end of the first and the second electronic elements on the bottom layer.

16. The motherboard interconnection device according to claim 15, wherein the first and the second electronic elements are selected from the group consisting of a capacitor and a resistor.

17. The motherboard interconnection device according to claim 15, wherein the first and the second electronic elements on the bottom layer are connected to the first part, and differential signals are transmitted to the first part through the first and the second electronic elements on the bottom layer of the motherboard interconnection device.
